(19) United States
(12) Patent Application Publication
(10) Pub. No.: US 2006/0033115 A1
(43) Pub. Date: Feb. 16, 2006

(54) Transparent, thermally stable light-emitting component comprising organic layers

(76) Inventors: Jan Blochwitz, Dresden (DE); Karl Leo, Dresden (DE); Martin Pfeiffer, Dresden (DE); Zhou Xiang, Dresden (DE)

Correspondence Address: BAKER & BOTTS, 30 ROCKEFELLER PLAZA, NEW YORK, NY, 10112, US

(21) Appl. No.: 10/496,414

(22) PCT Filed: Mar. 23, 2003
(86) PCT No.: PCT/DE03/01021

§ 371 Date: Sep. 19, 2005

(30) Foreign Application Priority Data
Mar. 28, 2002 (DE) 102 15 210.1

(51) Int. Cl. H05B 33/12

(52) U.S. Cl. 257/94; 428/690; 428/917; 313/504; 313/506

(57) ABSTRACT

The invention relates to a thermally stable, high efficient, transparent light-emitting component, which comprises organic layers, is run at low operating voltages and is simple to produce. The aim of the invention is to disclose a completely transparent (>70% transmission) organic light-emitting diode, which can be operated at a reduced operating voltage and is highly efficient at emitting light. To achieve this, according to the invention the hole transport layer adjacent to the anode is p-doped with a stable, acceptor-type organic molecular material with a high molecular mass, which leads to an increased hole conductivity in the doped layer, in comparison with the non-doped layer. Similarly, the electron injection layer adjacent to the cathode is n-doped with a stable, donor-type molecule with a high molecular mass and exhibits a significantly increased electron conductivity. Both doped layers can be thicker in the component than is possible with non-doped layers, without causing an increase in the operating voltage. This permits layers that are arranged below in particular the light-emitting layers, to be protected against damage during the production process, (sputter process), of the transparent electrode (e.g. ITO).

The present invention relates to a transparent and thermally stable light-emitting component comprising organic layers, and in particular to a transparent organic light-emitting diode according to the introductory parts of claims 1 or 2.

Ever since the demonstration, by Tang et al., 1987 [C. W. Tang et al., Appl. Phys. Lett. 51 (12), 913 (1987)], of low operating voltages, organic light-emitting diodes (OLED) have been promising candidates for the realization of large-area displays. They consist of a sequence of thin (typically 1 nm to 1 μm) layers of organic materials, which are preferably vacuum-deposited or deposited from the solution, e.g. by a spin-on operation. For this reason, these layers are typically more than 80% transparent in the visible spectral region. Otherwise, the OLED would have a low external light efficiency due to reabsorption. Contacting of the organic layers with an anode and a cathode is typically effected by means of at least one transparent electrode (comprising in the great majority of cases a transparent oxide, e.g. indium tin oxide) and a metallic contact. This transparent contact (e.g. the ITO) is typically situated directly on the substrate. In the case of at least one metallic contact, the OLED as a whole is not transparent, but reflective or scattering (due to appropriate modifying layers, which do not belong to the actual OLED structure). In case of the typical structure with the transparent electrode on the substrate, the OLED emits through the substrate situated on its lower side.

In the case of organic light-emitting diodes, light is produced and emitted by the light-emitting diode by the injection of charge carriers (electrons from one side, holes from the other side) from the contacts into the organic layers situated there-between, as a result of an externally applied voltage, the subsequent formation of excitons (electron-hole pairs) in an active zone, and the radiant recombination of these excitons.

The advantage of such organic components as compared with conventional inorganic components (semiconductors such as silicon, gallium arsenide) is that it is possible to produce very large-area display elements (visual displays, screens). Compared with inorganic materials, organic starting materials are relatively inexpensive (less expenditure of material and energy). Furthermore, these materials, because of their low processing temperature as compared with inorganic materials, can be deposited on flexible substrates, which opens up a wide variety of novel uses in display and illuminating technology.

The usual arrangement of such components comprising at least one non-transparent electrode consists of a sequence of one or more of the following layers:
1. Carrier, substrate;
2. Base electrode, hole-injecting (positive pole), typically transparent;
3. Hole-injecting layer;
4. Hole-transporting layer (HTL);
5. Light-emitting layer (EL);
6. Electron-transporting layer (ETL);
7. Electron-injecting layer;
8. Cover electrode, in most cases a metal having a low work function, electron-injecting (negative pole);
9. Encapsulation, to shut out environmental influences.

This is the most general case; in most cases some layers are omitted (except 2, 5 and 8), or else one layer combines several properties.

In the case of the above-described layer sequence, the light emission takes place through the transparent base electrode and the substrate, whereas the cover electrode consists of non-transparent metal layers. Current materials for the transparent base electrode are indium tin oxide (ITO) and related oxide semiconductors as injection contact for holes (a transparent degenerate semiconductor). Used for electron injection are base metals such as aluminum (Al), magnesium (Mg), calcium (Ca) or a mixed layer of Mg and silver (Ag), or such metals in combination with a thin layer of a salt such as lithium fluoride (LiF).

These OLEDs are usually non-transparent. However, there are applications for which the transparency is of decisive importance. Thus, a display element may be produced which in the switched-off state appears transparent, i.e. the surroundings behind it can be perceived, but will, in the turned-on condition, provide the viewer with information. In this connection, one could think of car windshields or displays for persons who must not be limited in their freedom of movement by the display (e.g., head-on displays for surveillance personnel). Such transparent OLEDs, which represent the basis for transparent displays, are known, e.g., from
1. G. Gu, V, Bulovic, P. E. Burrows, S. R. Forrest, Appl. Phys. Lett. 68, 2606 (1996);
2. G. Gu, V. Khalfin, S. R. Forrest, Appl. Phys. Lett. 73, 2399 (1998);
3. G. Parthasarathy et al., Appl. Phys. Lett. 72, 2138 (1997);
4. G. Parthasarathy et al., Adv. Mater. 11, 907 (1997);
5. G, Gu, G. Parthasarathy, S. R. Forrest, Appl. Phys. Lett. 74, 305 (1999).

In reference (1) above, the transparency is achieved by using the traditional transparent ITO anode as base electrode (that is, directly on the substrate). Here, it should be mentioned that it is favorable for the operating voltage of the OLED if the ITO anode is pretreated in a special way (e.g., ozone sputter, plasma incineration) in order to increase the work function of the anode (e.g. C. C. Wu et al., Appl. Phys. Lett. 70, 1348 (1997); G. Gu et al., Appl. Phys. Lett. 73, 2399 (1998). The work function of ITO can be varied e.g. by ozonization and/or oxygen-plasma incineration from about 4.2 eV to about 4.9 eV. In that case, it is possible to inject holes from the ITO anode into the hole transport layer in a more efficient manner. However, this pretreatment of the ITO anode is only possible if the anode is situated directly on the substrate. This structure of the OLED is denoted as non-inverted, and the structure of the OLED with the cathode on the substrate as inverted. In (1), a combination of a thin, semitransparent layer, a base metal (magnesium, stabilized through the admixture of silver) and a conductive transparent layer of the known ITO is used as cover electrode. The reason why this combination is necessary is that the work function of the ITO is too high for electrons to be efficiently injected directly into the electron transport layer and thereby make it possible to produce OLEDS having low operating voltages. This is avoided by means of the very thin magnesium intermediate layer. Because of the thin metallic intermediate layer the resulting component is semitransparent (transparency of the cover electrode about 50-80%), whereas the transparency of the ITO anode considered as fully transparent is over 90%. In reference (1), an additional ITO contact is deposited on the metallic intermediate layer by the sputter process, in order to ensure the lateral conductivity to the connection contacts of the OLED surroundings. The consequence of the ITO sputter process is that the metallic intermediate layer must not be designed thinner than 7.5 nm (1), as otherwise the sputter damages to the subjacent organic layers will be too high. Structures of this type are also described in the following patents: U.S. Pat. No. 5,703,436 (S. R. Forrest et al.), applied for on Mar. 6, 1996; U.S. Pat. No. 5,757,026 (S. R. Forrest et al.), applied for on Apr. 15, 1996; U.S. Pat. No. 5,969,474 (M. Arai), applied for on Oct. 24, 1997. Two OLEDS, one on top of the other, with the cathodes described in reference (1), are described in reference (2): here, a green and a red OLED arranged one upon the other (“stacked OLED”) are prepared. Since both OLEDs are semitransparent, it is possible, through suitable voltages at the now 3 electrodes, to choose the emission color in a targeted manner.

Another known realization of transparent OLEDs provides for an organic intermediate layer to improve the electron injection (references 3-5). In this case, an organic intermediate layer is arranged between the light-emitting layer (e.g. aluminum tris-quinolate, Alq3) and the transparent electrode (e.g. ITO) used as cathode. In most cases, this intermediate layer is copper phthalocyanine (CuPc). Actually, this material is a hole-transport material (higher hole mobility than electron mobility). To be sure, it has the advantage of high thermal stability. Thus, the sputtered-on cover electrode cannot do as much damage to the subjacent organic layers. An advantage and at the same time a disadvantage of this CuPc intermediate layer is the small band gap (distance between HOMO—highest occupied molecular orbital—and LUMO—lowest unoccupied molecular orbital). The advantage is that because of the low LUMO position electrons can be injected from ITO relatively easily, but on account of the small band gap the absorption in the visible region is high. For this reason, the thickness of the CuPc layer must be limited to below 10 nm. Moreover, the injection of electrons from CuPc into Alq3 or another emission material is difficult, since their LUMOs lie generally higher. A further realization of the transparent cathode at the top of the OLED was proposed by Pioneer [U.S. Pat. No. 5,457,565 (T. Namiki) applied for on Nov. 18, 1993]. In this case, a thin layer of an alkaline earth metal oxide (e.g. LiO2) is used instead of the CuPc layer. This improves the otherwise poor electron injection from the transparent cathode into the light-emitting layer.

A further realization of the transparent OLED (G. Parthasarathy et al., Appl. Phys. Left. 76, 2128 (2000), WO Patent 01/67825 A1 (G. Parthasarathy), applied for on Mar. 7, 2001, priority date Mar. 9, 2000) provides for an additional electron transport layer (e.g. BCP=bathocuproine having a high electron mobility) in contact with the transparent cathode (e.g., ITO). There is an approximately 1 nm thick pure layer of the alkali metal lithium (Li) either between the light-emitting layer and the thin (<10 nm) electron transport layer or between the electron transport layer and the ITO cathode. This Li intermediate layer drastically increases the electron injection from the transparent electrode. This effect is explained by a diffusion of the Li atoms into the organic layer and subsequent “doping,” with the formation of a highly conductive intermediate layer (degenerate semiconductor). Then, a transparent contact layer (mostly ITO) is placed on the latter.

The above studies make the following points clear:
1. The choice of transparent electrodes is limited (essentially to ITO or similar degenerate inorganic semiconductors).
2. The work functions of the transparent electrodes mainly favor hole injection, but for this, too, a special treatment of the anode is required, in order to further reduce its work function.
3. All previous developments aim at finding a suitable intermediate layer which improves the injection of electrons into the organic layers.

It is known for light-emitting diodes from inorganic semiconductors that it is possible, through highly doped peripheral layers, to obtain thin space charge zones which, even in the presence of energy barriers, lead to efficient injection of charge carriers by tunneling. Here, the term “doping” is understood to mean (as is usual for inorganic semiconductors) the targeted influencing of the conductivity of the semiconductor layer through admixture of foreign atoms/molecules. For organic semiconductors, the term “doping” is often understood to mean the admixture, to the organic layer, of specific emitter molecules; here, a distinction should be made. The doping of organic materials was described in U.S. Pat. No. 5,093,698, applied for on Feb. 12, 1991. However, in the case of practical applications, this leads to problems with the energy adaptation of the different layers and to reduction of the efficiency of the LEDs having doped layers.

The object of the present invention is to provide a fully transparent (>70% transmission) organic light-emitting diode which can be operated at a low operating voltage and has a high light-emission efficiency. At the same time, the protection of all organic layers, in particular of the light-emitting layers, against damages during preparation of the transparent cover contact should be assured. The resulting component should be stable (operating temperature range up to 80° C., long-term stability).

According to the invention this object is achieved in combination with the features mentioned in the introductory part of claim 1 in such a way that the hole transport layer is p-doped with an acceptor-type organic material and the electron transport layer is n-doped with a donor-type organic material, and the molecular masses of the dopants are greater than 200 g/mole.

Furthermore, this object if achieved in connection with the features mentioned in the introductory part of claim 2 in such a way that the electron transport layer is n-doped with a donor-type organic material and the hole transport layer is p-doped with an acceptor-type organic material, and the molecular masses of the dopants are greater than 200 g/mole.

As described in Patent Application DE 101 35 513.0 (Leo et al., submitted on Jul. 20, 2001), the layer sequence of the OLED can be reversed, thus the hole-injecting (transparent) contact (anode) can be realized as cover electrode. The result of this is usually that in the case of inverted organic light-emitting diodes the operating voltages are considerably higher than with comparable noninverted structures. The reason for this is that the injection from the contacts into the organic layers is worse, because the work function of the contacts can no longer be optimized in a targeted manner.

In the solution of the task according to the invention, the injection of charge carriers from the electrodes into the organic layers (whether hole- or electron-transporting layers) does not depend so strongly on the work function of the electrodes itself. As a result it is also possible to use, on both sides of the OLED component, the same electrode type, thus, e.g., two equal transparent electrodes, e.g. ITO.

The cause of the increase of conductivity is an increased density of equilibrium charge carriers in the layer. Here, the transport layer can have higher layer thicknesses than is possible with undoped layers (typically 20-40 nm), without drastically increasing the operating voltage. Similarly, the electron-injecting layer adjacent to the cathode is n-doped with a donor-type molecule (preferably an organic molecule or fragments thereof, see Patent Application DE XXX, Ansgars patent), which leads to an increase of the electron conductivity, due to higher intrinsic charge-carrier density. This layer, too, can be made thicker in the component than would be possible with undoped layers, since that would lead to an increase of the operating voltage. Thus, both layers are thick enough to protect the subjacent layers against damages during the production process (sputter process) of the transparent electrode (e.g. ITO).

In the doped charge-carrier transport layers (holes or electrons) on the electrodes (anode or cathode), a thin space charge zone is created through which the charge carriers can be injected in an efficient manner. Because of the tunnel injection, the injection is no longer hindered by the very thin space charge zone, even in case of an energetically high barrier. The charge-carrier transport layer is preferably doped by an admixture of an organic or inorganic substance (dopant). These large molecules are incorporated in a stable manner into the matrix molecule skeleton of the of the charge-carrier transport layers. As a result, a high degree of stability is obtained during operation of the OLED (no diffusion) as well as under thermal load.

In Patent Application DE 100 58 578.7 filed on Nov. 25, 2000 (see also X. Zhou et al., Appl. Phys. Left. 78, 410 (2001)), it is described that organic light-emitting diodes comprising doped transport layers only show an efficient light emission when the doped transport layers are combined with blocking layers in an appropriate manner. Hence, in an advantageous embodiment, the transparent light-emitting diodes are also provided with blocking layers. The blocking layer is always located between the charge-carrier transport layer and a light-emitting layer of the component, in which the conversion of the electric energy of the charge carriers injected by current flow through the component into light takes place. According to the invention the substances of the blocking layers are selected so that when voltage is applied (in the direction of the operating voltage), because of their energy levels the majority charge carriers (HTL side: holes, ETL side: electrons) are not too strongly hindered at the doped charge-carrier transport layer/blocking layer interface (low barrier), but the minority charge carriers are efficiently arrested at the light-emitting layer/blocking layer interface (high barrier). Moreover, the barrier height for the injection of charge carriers from the blocking layer into the emitting layer should be so small that the conversion of a charge-carrier pair at the interface into an exciton in the emitting layer is energetically advantageous. This prevents exciplex formation at the interfaces of the light-emitting layer, which reduces the efficiency of the light emission. Since the charge-carrier transport layers preferably have a high band gap, the blocking layers can be chosen to be very thin, since in spite of this no tunneling of charge carriers from the light-emitting layer in energy conditions of the charge-carrier transport layers is possible. This permits obtaining a low operating voltage despite blocking layers.

An advantageous embodiment of a structure of transparent OLED according to the invention in accordance with claim 1 contains the following layers (non-inverted structure):
1 Carrier, substrate;
2 Transparent electrode, e.g., ITO, hole-injecting (anode=positive pole);
3 p-Doped, hole-injecting and transporting layer;
4 Thin hole-side blocking layer made of a material whose band positions match the band positions of the layers enclosing it;
5 Light-emitting layer (possibly doped with emitter dye);
6 Thin electron-side blocking layer of a material whose band positions match the band positions of the layers enclosing it;
7 n-Doped electron-injecting and transporting layer;
8 Transparent electrode, electron-injecting (cathode=negative pole);
9 Encapsulation, to shut out environmental influences.

A second advantageous embodiment of a structure of a transparent OLED according to the invention in accordance with to claim 2 contains the following layers (inverted structure):
1 Carrier, substrate;
2a Transparent electrode, e.g. ITO, electron-injecting (cathode=negative pole);
3a n-Doped, electron-injecting and transporting layer;
4a Thin electron-side blocking layer of a material whose band positions match the band positions of the layers surrounding it;
5a Light-emitting layer (possibly doped with emitter dye);
6a Thin hole-side blocking layer of a material whose band positions match the band positions of the layers surrounding it;
7a p-Doped hole-injecting and transporting layer;
8a Transparent electrode, hole-injecting (anode=positive pole), e.g. ITO;
9 Encapsulation, to keep out environmental influences.

It is also within the scope of the invention when only one blocking layer is used, because the band positions of the injecting and transporting layer and of the light-emitting layer already match one another on one side. Furthermore, the functions of charge-carrier injection and of charge-carrier transport into layers 3 and 7 may be divided among several layers, of which at least one (namely that adjacent to the electrodes) is doped. When the doped layer is not directly located on the respective electrode, then all layers between the doped layer and the respective electrode must be so thin (<10 nm) that they can efficiently be tunneled through by charge carriers. These layers can be thicker when they have a very high conductivity (the bulk resistance of these layers must be smaller than that of the neighboring doped layer). Then the intermediate layers should be considered, within the context of the invention, as a part of the electrode. The molar doping concentrations typically lie in the range of 1:10 to 1:10000. The dopants are organic molecules having molecular masses above 200 g/mole.

Below, the invention will be explained in greater detail by means of examples. In the drawings,

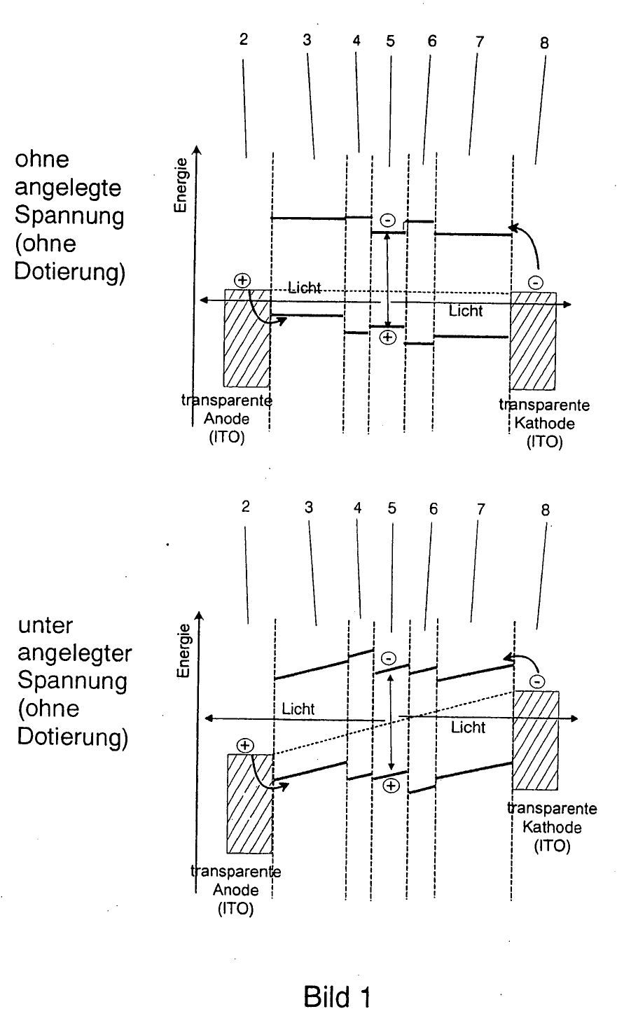

FIG. 1 is an energy diagram of a transparent OLED in the hitherto customary embodiment (without doping; the numbers refer to the above-described non-inverted layer structure of the OLED according to claim 1). Described in the upper part is the position of the energy levels (HOMO and LUMO) without external voltage (it can be seen that both electrodes have the same work function), and in the lower part with applied external voltage. Here, for the sake of simplicity, the blocking layers 4 and 6 are also drawn in.

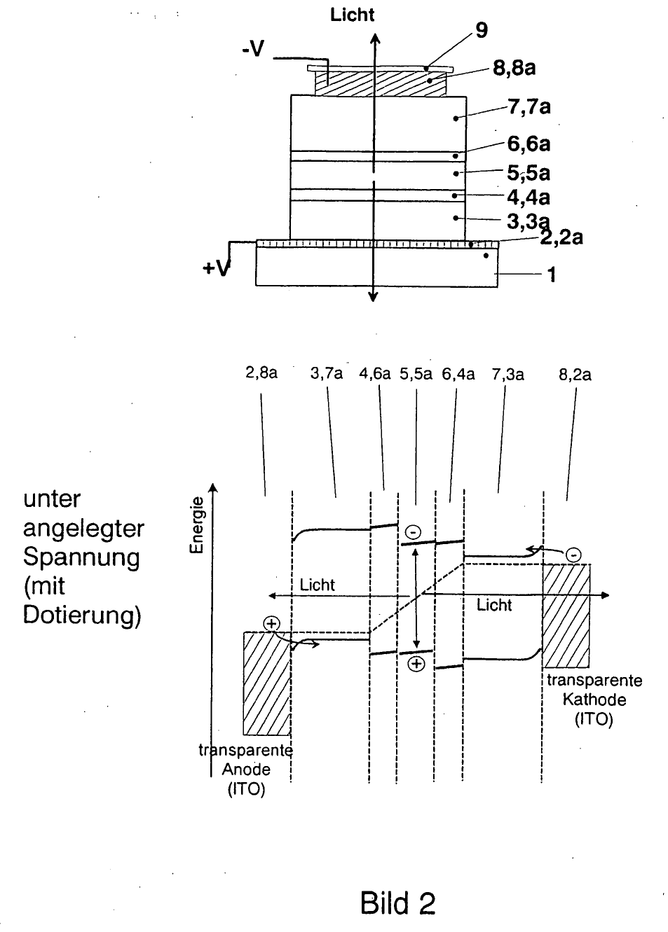

FIG. 2 is an energy diagram of a transparent OLED with doped charge-carrier transport layers and matching blocking layers (note the band bending adjacent to the contact layers, here of ITO in both cases). The numbers refer to both of the above-described embodiments. Shown in the upper part is the structure of the component which, because of its transparency, emits light in both directions; shown in the lower part is the band structure.

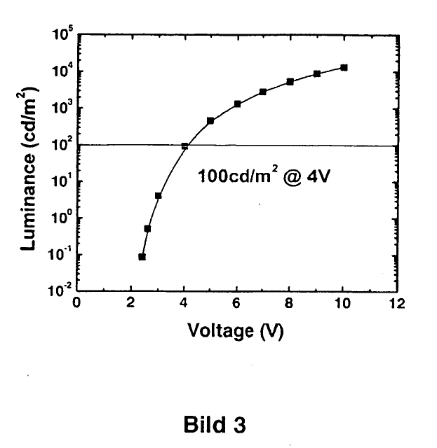

FIG. 3 shows the luminance vs. voltage curve of the embodiment presented below; the typical monitor luminance of 100 cd/m² is attained already at 4 V. The efficiency is 2 cd/A. However, here, for technical reasons, no transparent contact (e.g.

ITO) is used as anode material, but is simulated by a semitransparent (50%) gold contact. Thus, this is a semitransparent OLED.

In the embodiment shown in FIG. 1 no space charge zone occurs at the contacts. This embodiment calls for a low energy barrier for the charge-carrier injection. This, under certain circumstances, cannot be achieved at all or only with difficulty when using available materials (see prior art, above). Hence, the injection of charge carriers from the contacts is not so effective. The OLED shows an increased operating voltage.

According to the invention, the disadvantage of the previous structures is avoided by transparent OLEDs with doped injection and transport layers, optionally in combination with blocking layers. FIG. 2 shows a suitable arrangement. In this case the charge-carrier-injecting and conducting layers 3 and 7 are doped, so that space charge zones are formed at the interfaces to contacts 2 and 8. A condition is that the doping is high enough to make it possible for these space charge zones to be easily tunneled through. That such dopings are possible was already shown at least for the p-doping of the hole transport layer in the literature for nontransparent light-emitting diodes (X. Q. Zhou et al., Appl. Phys. Lett. 78, 410 (2001); J. Blochwitz et al., Organic Electronics 2, 97 (2001)).

This arrangement is distinguished by the following advantages:
Excellent injection of charge carriers from the electrodes into the doped charge-carrier transport layers.
Not being dependent on the detailed preparation of the charge-carrier-injecting materials 2 and 8.
The possibility of choosing, for the electrodes 2 and 8, also materials having comparatively high barriers for the charge-carrier injection; e.g., the same material in both cases, e.g. ITO.

A preferred embodiment is given below. To be sure, in this example there is no n-doping as yet of the electron transport layer with stable large organic dopants. Shown as an example of the effectiveness of the concept of transparent OLED with doped organic transport layers is an embodiment with the nonstable n-doping of a typical electron transport material (Bphen=bathophenanthroline) with Li (U.S. Pat. No. 6,013,384 (J. Kido et al.), applied for on Jan. 22, 1998; J. Kido et al., Appl. Phys. Lett. 73, 2866 (1998)). As already described in the prior art, this approximately 1:1 mixture of Li and Bphen can demonstrate the effectiveness of the doping. To be sure, this layer is not stable thermally and operationally. Since in the case of this doping, very high dopant concentrations occur, it must also be assumed that the mechanism of doping is different. On doping with organic molecules and doping ratios of between 1:10 and 1:10000, it can be assumed that the dopant does not significantly affect the structure of the charge-carrier transport layer. This cannot be assumed in the case of a 1:1 admixture of doping metals, e.g. Li.

The OLED has the following layer structure (inverted structure):
1a Substrate, e.g. glass;
2a Cathode: ITO as purchased, untreated;
3a n-Doped electron-transporting layer: 20 nm Bphen:Li, 1:1 molecular mixing ratio;
4a Electron-side blocking layer: 10 nm Bphen;
5a Electroluminescent layer: 20 nm Alq₃, may be mixed with emitter dopants in order to increate the internal quantum yield of the light production;
6a Hole-side blocking layer: 5 nm triphenyldiamine (TPD);
7a p-Doped hole-transporting layer: 100 nm Starburst m-MTDATA 50:1 doped with F₄-TCNQ dopant (thermally stable to about 80° C.);
8a Transparent electrode (anode) indium tin oxide (ITO).

The mixed layers 3 and 7 are prepared by a vapor deposition process in vacuo by mixed evaporation. In principle, such layers can also be prepared by other processes as well, such as, e.g. vapor deposition of the substances one upon the other, followed by a possibly temperature-controlled diffusion of the substances into one another; or by another type of deposition (e.g. spin-on deposition) of the already mixed substances in or outside of vacuum. The blocking layers 3 and 6 were likewise vapor-deposited in vacuo, but can also be prepared by another process, e.g. by spin-on deposition in or outside of vacuum.

FIG. 3 shows the luminance vs. voltage curve of a semitransparent OLED. For test purposes, a semitransparent gold contact (50% transmission) was used. For a luminance of 100 cd/M² an operating voltage of 4 V is needed. This is one of the lowest operating voltages realized for transparent OLEDs, especially with an inverted layer structure. This OLED demonstrates the realizability of the concept presented herein. Because of the semitransparent cover electrode, the external current efficiency only attains a value of about 2 cd/A and not 5 cd/A as it could be maximally expected for OLEDs with pure Alq3 as emitter layer.

The use of doped layers according to the invention makes it possible to attain nearly the same low operating voltages and high efficiencies in a transparent structure as occur in a traditional structure with one-sided emission through the substrate. This is due, as described, to the efficient charge-carrier injection, which, thanks to the doping, is relatively independent of the exact work function of the transparent contact materials. In this way the same electrode materials (or transparent electrode materials of only slightly different work functions) can be used as electron-injecting contact and hole-injecting contact.

From the examples, it is obvious to a person skilled in the art that many modifications and variations of the invention described herein are possible which fall within the scope of the invention. For example, transparent contacts other than ITO can be used as anode materials (e.g., as in H. Kim et al., Appl. Phys. Lett. 76, 259 (2000); H. Kim et al., Appl. Phys. Lett. 78, 1050 (2001)). Furthermore, it is in accordance with the invention to make up the transparent electrodes by combining a sufficiently thin intermediate layer of a nontransparent metal (e.g. silver or gold) and a thick layer of the transparent conductive material. In that case the thickness of the intermediate layer must and can be so thin (since because of the thick doped charge-carrier transport layers no damages to the light-emitting layers are to be expected during sputter) that the whole component is still transparent in the above sense (transparency in the entire visible spectral region >75%). A further embodiment conforming to the invention uses, for the doped electron transport layer, a material whose LUMO level is too deep (in the sense of FIGS. 1 and 2 layer: 7 or 3a) to be able to efficiently inject electrons into the blocking layer and light-emitting layer (6 or 4a, and 5 or 5a, respectively) (thus, greater barriers than shown in FIG. 2). In that case, it is possible to use between the n-doped electron transport layer (7 or 3a) and blocking layer (6 or 4a) or the light-emitting layer (5 or 5a) a very thin (<2.5 nm) layer of a metal having a lower work function than the LUMO level of the doped transport layer. The metal layer must be so thin that the overall transparency of the component is not significantly reduced (see L. S. Hung, M. G. Mason, Appl. Phys. Lett. 78, 3732 (2001).

### EXPLANATION OF REFERENCE NUMBERS

1 Substrate
2, 2a Anode or cathode, respectively
3, 3a Hole transport layer or electron transport layer (doped), respectively
4, 4a Hole-side or electron-side thin blocking layer, respectively
5, 5a Light emitting layer
6, 6a Electron-side or hole-side blocking layer, respectively
7, 7a Hole transport layer or electron transport layer (doped), respectively
8, 8a Anode or cathode, respectively
9 Encapsulation

1-20. (canceled)

21. A transparent, thermally stable light-emitting component having organic layers, comprising:
a transparent substrate;
a transparent anode;
a hole transport layer adjacent to the anode;
at least one light-emitting layer;
a charge-carrier transport layer for electrons; and
a transparent cathode,
wherein the hole transport layer is p-doped with an acceptor-type organic material and the electron transport layer is n-doped with a donor-type organic material, and the molecular masses of the dopants are greater than 200 g/mole.

22. A light-emitting component according to claim 21, further comprising a hole-side blocking layer is provided between the doped hole transport layer and the light-emitting layer.

23. A light-emitting component according to claim 21, further comprising an electron-side blocking layer provided between the doped electron transport layer and the light-emitting layer.

24. A light-emitting component according to claim 21, further comprising transparent contact layers disposed adjacent at least one of said hole transport layer on same change carrier transport layer, wherein the doping concentration of the organic dopants are chosen so high that a quasi-ohmic injection takes place from the contact layers into the charge-carrier transport layers.

25. A light-emitting component according to claim 24, wherein the contact layers consist of indium tin oxide (ITO).

26. A light-emitting component according to claim 24, wherein the transparent contacts consist of a transparent material similar to ITO, thus of another degenerate oxide semiconductor.

27. A light-emitting component according to claim 24, wherein the two transparent contacts consist of different transparent contact materials.

28. A light-emitting component according to claim 21, further comprising a thin contact-improving layer provided in each case between electron transport layer and cathode and/or between the anode and the hole transport layer, both of which can be readily tunneled through.

29. A light-emitting component according to claim 21, wherein the light-emitting layer is a mixed layer of several materials.

30. A light-emitting component according to claim 21, wherein the p-doped hole transport layer consists of an organic main substance and an acceptor-type doping substance, and the molecular mass of the dopants is greater than 200 g/mole.

31. A light-emitting component according to claim 21, wherein the electron transporting layer is n-doped by the mixture of an organic main substance and a donor-type doping substance, and the molecular mass of the dopants is greater than 200 g/mole.

32. A light-emitting component according to claim 21, wherein the transparent cathode or transparent anode situated on top is provided with a transparent protective layer.

33. A light-emitting component according to claim 21, wherein the transparent cathode or anode situated on top is provided with a very thin metallic intermediate layer to the subjacent doped charge-carrier transport layer, so that the transparency in the entire visible spectral region is still over 75%.

34. A light-emitting component according to claim 21 wherein the transparent anode or cathode situated at the bottom is provided with a very thin metallic intermediate layer to the superjacent doped charge-carrier transport layer, so that the transparency in the entire visible spectral region is still over 75%.

35. A light-emitting component according to claim 21, wherein the sequence of p-doped hole transport layer and transparent anode is repeatedly provided in a component.

36. A light-emitting component according to claim 21, wherein the sequence of n-doped electron transport layer and transparent cathode is repeatedly provided in a component.

37. A light-emitting component according to claim 21, further comprising a thin metallic electron-injection-promoting layer presented between the doped electron transport layer and the blocking layer or the light-emitting layer.

38. A light-emitting component according to claim 21, wherein the molar concentration of admixture in the hole transport layer and/or in the electron transport layer is in the range of 1:100,000 to 1:10, calculated on the ratio of doping molecules to main-substance molecules.

39. A light-emitting component according to claim 22, wherein the layer thickness of the hole transport layer of the electron transport layer, of the light-emitting layer and of the blocking layers lies in the range of 0.1 nm to 50 μm.

40. A transparent, thermally stable light-emitting component having organic layers, comprising:
a transparent substrate;
a transparent cathode;
an electron transport layer adjacent to the anode;
at least one light-emitting layer a charge-carrier transport layer for holes; and
a transparent anode;
wherein the electron transport layer is n-doped with a donor-type organic material and the hole transport layer is p-doped with an acceptor-type organic material, and the molecular masses of the dopants are greater than 200 g/mole.

41. A light-emitting component according to claim 40, further comprising a hole-side blocking layer is provided between the doped hole transport layer and the light-emitting layer.

42. A light-emitting component according to claim 40, further comprising an electron-side blocking layer provided between the doped electron transport layer and the light-emitting layer.

43. A light-emitting component according to claim 40, further comprising transparent contact layers disposed adjacent at least one of said hole transport layer on same change carrier transport layer, wherein the doping concentration of the organic dopants are chosen so high that a quasi-ohmic injection takes place from the contact layers into the charge-carrier transport layers.

44. A light-emitting component according to claim 43, wherein the contact layers consist of indium tin oxide (ITO).

45. A light-emitting component according to claim 43, wherein the transparent contacts consist of a transparent material similar to ITO, thus of another degenerate oxide semiconductor.

46. A light-emitting component according to claim 43, wherein the two transparent contacts consist of different transparent contact materials.

47. A light-emitting component according to claim 40, further comprising a thin contact-improving layer provided in each case between electron transport layer and cathode and/or between the anode and the hole transport layer, both of which can be readily tunneled through.

48. A light-emitting component according to claim 40, wherein the light-emitting layer is a mixed layer of several materials.

49. A light-emitting component according to claim 40, wherein the p-doped hole transport layer consists of an organic main substance and an acceptor-type doping substance, and the molecular mass of the dopants is greater than 200 g/mole.

50. A light-emitting component according to claim 40, wherein the electron transporting layer is n-doped by the mixture of an organic main substance and a donor-type doping substance, and the molecular mass of the dopants is greater than 200 g/mole.

51. A light-emitting component according to claim 40, wherein the transparent cathode or transparent anode situated on top is provided with a transparent protective layer.

52. A light-emitting component according to claims 40, wherein the transparent cathode or anode situated on top is provided with a very thin metallic intermediate layer to the subjacent doped charge-carrier transport layer, so that the transparency in the entire visible spectral region is still over 75%.

53. A light-emitting component according to claim 40 wherein the transparent anode or cathode situated at the bottom is provided with a very thin metallic intermediate layer to the superjacent doped charge-carrier transport layer, so that the transparency in the entire visible spectral region is still over 75%.

54. A light-emitting component according to claim 40, wherein the sequence of p-doped hole transport layer and transparent anode is repeatedly provided in a component.

55. A light-emitting component according to claim 40, wherein the sequence of n-doped electron transport layer and transparent cathode is repeatedly provided in a component.

56. A light-emitting component according to claim 40, further comprising a thin metallic electron-injection-promoting layer presented between the doped electron transport layer and the blocking layer or the light-emitting layer.

57. A light-emitting component according to claim 40, wherein the molar concentration of admixture in the hole transport layer and/or in the electron transport layer is in the range of 1:100,000 to 1:10, calculated on the ratio of doping molecules to main-substance molecules.

58. A light-emitting component according to claim 41, wherein the layer thickness of the hole transport layer of the electron transport layer, of the light-emitting layer and of the blocking layers lies in the range of 0.1 nm to 50 μm.
